(19) United States
(12) Patent Application Publication
(10) Pub. No.: US 2010/0033353 A1
(43) Pub. Date: Feb. 11, 2010

(54) ELECTRONIC DEVICE AND ANTI-MISOPERATION METHOD FOR KEY MODULE

(75) Inventor: YUAN-CHEN CHANG, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: CHI MEI COMMUNICATION SYSTEMS, INC., Tu-Cheng City (TW)

(21) Appl. No.: 12/414,774

(22) Filed: Mar. 31, 2009

(30) Foreign Application Priority Data
Aug. 8, 2008 (CN) 200810303614.1

(51) Int. Cl. H03M 11/00

(52) U.S. Cl. 341/24

(57) ABSTRACT

An electronic device includes a key module, an active area positioned under the key module, an IC electronically connected to the active area, and a CPU electronically connected to the IC. The key module includes a plurality of pressing keys, a plurality of touch keys, and at least one error-detecting touch key positioned between the pressing keys and the touch keys. The active area includes a plurality of pressing regions under the pressing keys, a plurality of touch regions under the touch keys, and at least one error-detecting region under the error-detecting touch key. The IC processes the signals sent by the pressing regions, the touch regions or the at least one error-detecting region. The CPU executes instructions corresponding to the signals processed by the IC.

### BACKGROUND

1. Technical Field

The present disclosure generally relates to an electronic device and an anti-misoperation method for a key module of the electronic device.

2. Description of Related Art

Electronic devices, such as mobile phones, notebook computers, or personal digital assistants, are very popular and widely used. Those electronic devices usually have keys to input commands. Generally, the keys of the electronic device are either buttons or touch sensitive areas of the device. A key module having both buttons and touch sensitive areas are uncommon, because of a high probability of misoperation by a user.

Referring to FIG. 6, a key module (not labeled) consisting of a plurality of pressing keys 10 and a plurality of touch keys 20, is shown. The pressing keys 10 are positioned adjacent to the touch keys 20. When a user presses one of the pressing keys 10, the user may also inadvertently press on the adjacent touch key 20 simultaneously (shown in FIG. 7). As a result, the pressing key 10 and the adjacent touch key 20 may trigger different functions at the same time, which may result in an error.

What is needed, therefore, is an electronic device and an anti-misoperation method for a key module that overcomes the above mentioned disadvantage.

### BRIEF DESCRIPTION OF THE DRAWINGS

The components in the drawings are not necessarily drawn to scale, the emphasis instead being placed upon clearly illustrating the principles of the present disclosure. Moreover, in the drawings, like reference numerals designate corresponding parts throughout the several views, and all the views are schematic.

FIG. 1 is a plan view of an embodiment of a mobile phone including a key module, an active area, an integrated circuit (IC), and a central processing unit (CPU).

FIG. 2 is a plan view showing the active area under the key module of FIG. 1.

FIG. 3 is a block diagram of the active area, the IC and the CPU.

FIG. 4 is similar to FIG. 2, showing an area of the key module being pressed by a user.

FIG. 5 is a flowchart of an anti-misoperation method for the key module of FIG. 1.

FIG. 6 is a plan view of a typical key module consisting of pressing keys and touch keys.

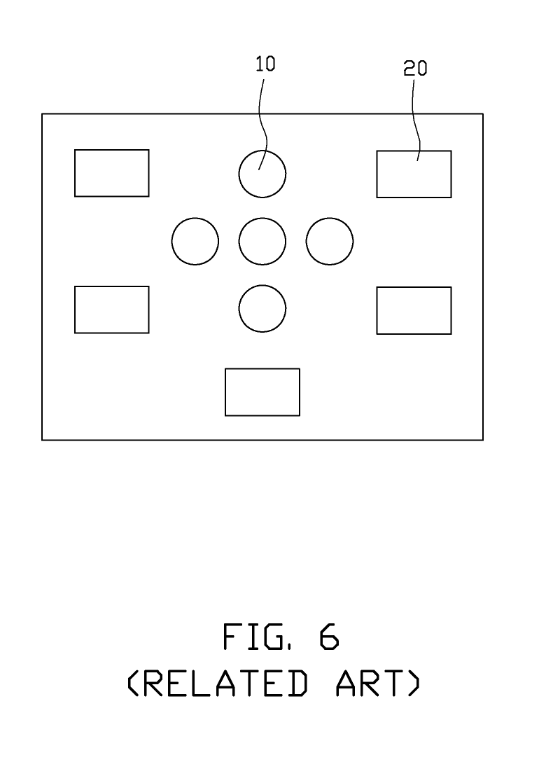

FIG. 7 is similar to FIG. 6, showing an area of the typical key module being pressed by a user.

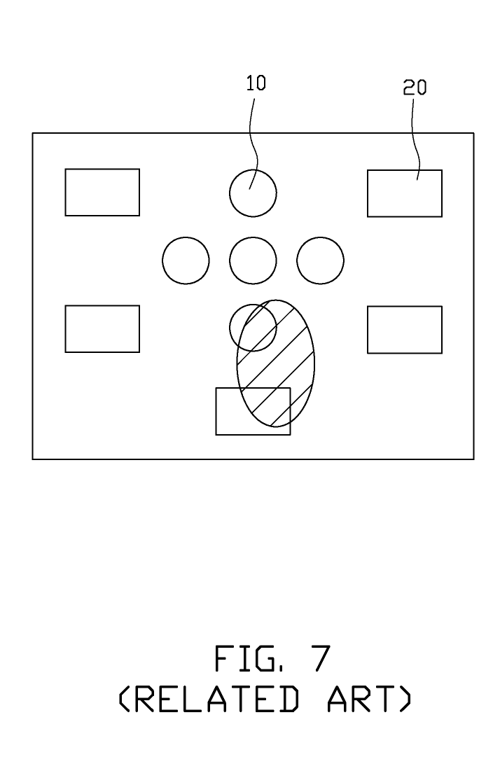

### DETAILED DESCRIPTION

The present anti-misoperation method for the key module may be used in electronic devices such as mobile phones, notebook computers, or personal digital assistants. Hereinafter, for the purposes of conveniently describing the present disclosure, an embodiment of the anti-misoperation method for the key module as used in a mobile phone is described and illustrated.

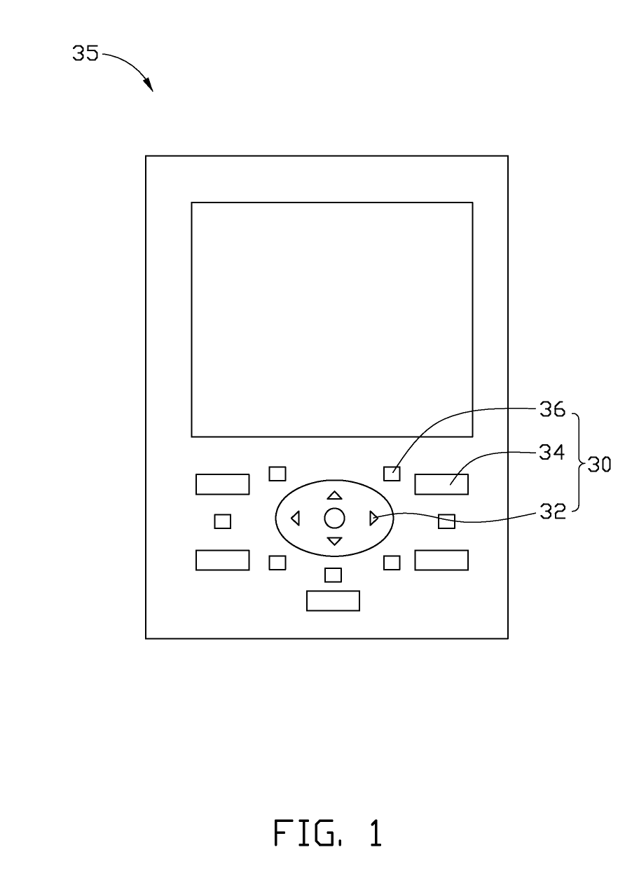

Referring to FIG. 1, a mobile phone 35 includes a key module 30. The key module 30 includes, for exemplary purposes, five pressing keys 32 centrally positioned below a screen of the mobile phone 35, and five touch keys 34 positioned around the pressing keys 32. The mobile phone 35 further includes a plurality of error-detecting touch keys 36 positioned so that areas between the pressing key 32 and the touch key 34 and between one touch key 34 and another touch key 34 have at least one error-detecting touch key 36.

In the illustrated embodiment, the touch keys 34 and the error-detecting touch keys 36 may be capacitive, resistive, infrared, or surface acoustic-wave types.

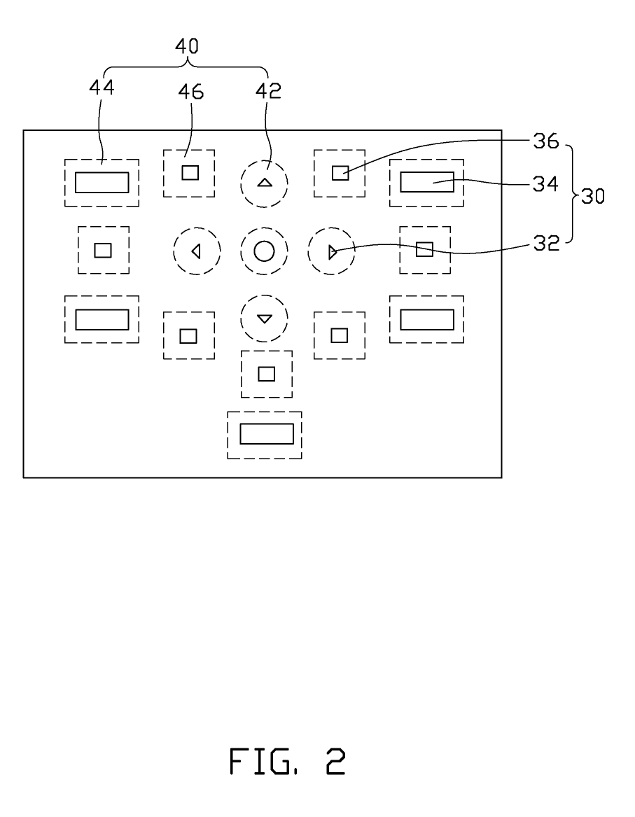

Referring also to FIG. 2, the mobile phone 35 includes an active area 40 positioned under the key module 30. The active area 40 includes five pressing regions 42 under the pressing keys 32, five touch regions 44 under the touch keys 34, and a plurality of error-detecting regions 46 under the error-detecting touch keys 36. The error-detecting regions 46 are positioned so that areas between the pressing region 42 and the touch region 44 and between one touch region 44 and another touch region 44 have at least one of the error-detecting regions 46. When one of the pressing keys 32 is pressed by a user, the pressing region 42 is triggered to send a corresponding signal. Similarly, when one of the touch keys 34 or the error-detecting touch keys 36 is touched by the user, the touch region 44 or the error-detecting region 46 is triggered to send a corresponding signal.

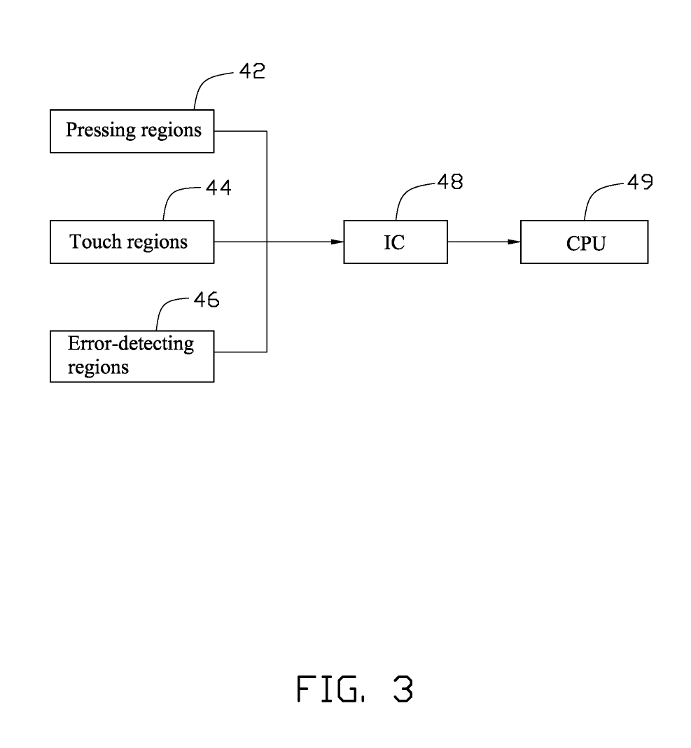

Referring to FIG. 3, the mobile phone 35 includes an integrated circuit (IC) 48 and a central processing unit (CPU) 49. The IC 48 is electronically connected to the active area 40, and processes the signals sent by the pressing regions 42, the touch regions 44, and the error-detecting regions 46. The CPU 49 is electronically connected to the IC 48, and executes instructions corresponding to the signals processed by the IC 48.

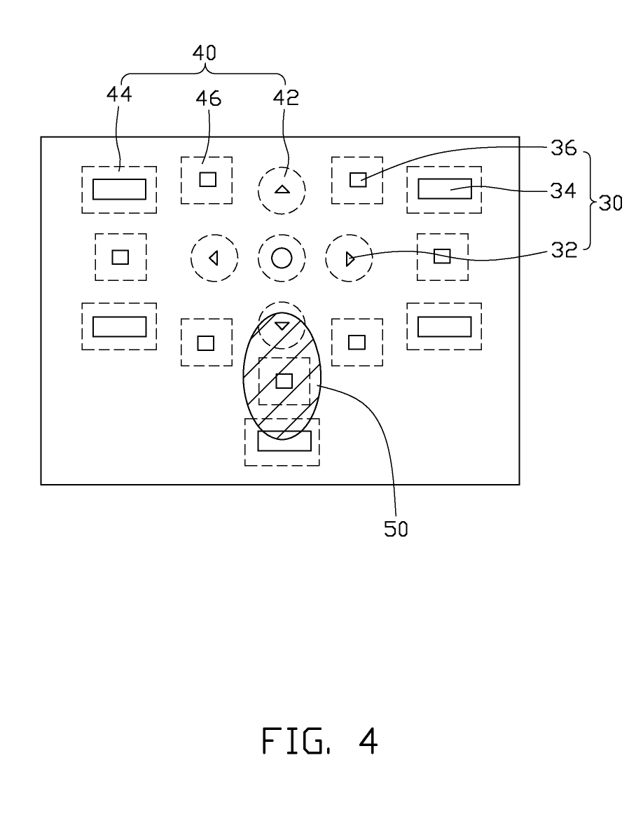

Referring to FIG. 4, when an area 50, for example, is pressed by the user, the pressing region 42, the adjacent touch region 44 and the adjacent error-detecting region 46 are triggered simultaneously. In other conditions, maybe only the pressing region 42 and the adjacent touch region 44 are triggered simultaneously, or only the pressing region 42 and the adjacent error-detecting region 46 are triggered simultaneously.

Therefore, the three regions may be triggered in any combination: one from each of the pressing regions 42, touch regions 44, and error-detecting regions 46. The action taken, whether the IC 48 transmits signals sent by the regions to the CPU 49 or not, is decided according to the combination of the triggered regions as illustrated in Table 1 below.

TABLE 1

| | pressing | touch region | error-detecting | |
|---|---|---|---|---|
| combinations | region 42 | 44 | region 46 | the action of the IC 48 |
| first | triggered | un-triggered | un-triggered | transmits signal sent by pressing |
| | | | | region 42 to the CPU 49 |
| second | un-triggered | triggered | un-triggered | transmits signal sent by touch |
| | | | | region 44 to the CPU 49 |
| third | un-triggered | un-triggered | triggered | doesn't transmit any signal to the |
| | | | | CPU 49 |
| fourth | un-triggered | triggered | triggered | transmits signal sent by touch |
| | | | | region 44 to the CPU 49 |
| fifth | triggered | un-triggered | triggered | transmits signal sent by pressing |
| | | | | region 42 to the CPU 49 |
| sixth | triggered | triggered | un-triggered | transmits signals sent by pressing |
| | | | | region 42 and touch region 44 to |
| | | | | the CPU 49 to further process |
| seventh | triggered | triggered | triggered | doesn't transmit any signal to the |
| | | | | CPU 49 |
| eighth | un-triggered | un-triggered | un-triggered | doesn't transmit any signal to the |
| | | | | CPU 49 |

Since the area between the pressing key 32 and the touch key 34 have at least one error-detecting touch key 36, if the pressing region 42 and the adjacent touch region 44 are triggered simultaneously, the adjacent error-detecting region 46 may also be triggered simultaneously. Therefore, the IC 48 does not transmit any signal to the CPU 49, and the pressing key 32 and the touch key 34 are inoperative. Thus, the probability of misoperation may decrease. In the sixth combination, an anti-misoperation control program may be set in the mobile phone 35 to prevent the CPU 49 from executing an instruction in error. It should be pointed out that, the occurrences of the sixth combination may be decreased or even avoided by utilizing alternate designs of the error-detecting touch keys 36. For example, the error-detecting keys 36 may be changed into a ring-shaped error-detecting key, and positioned around the pressing keys 32. In addition, the number of the error-detecting keys 36 may be increased, and the distribution of the error-detecting keys 36 may be varied.

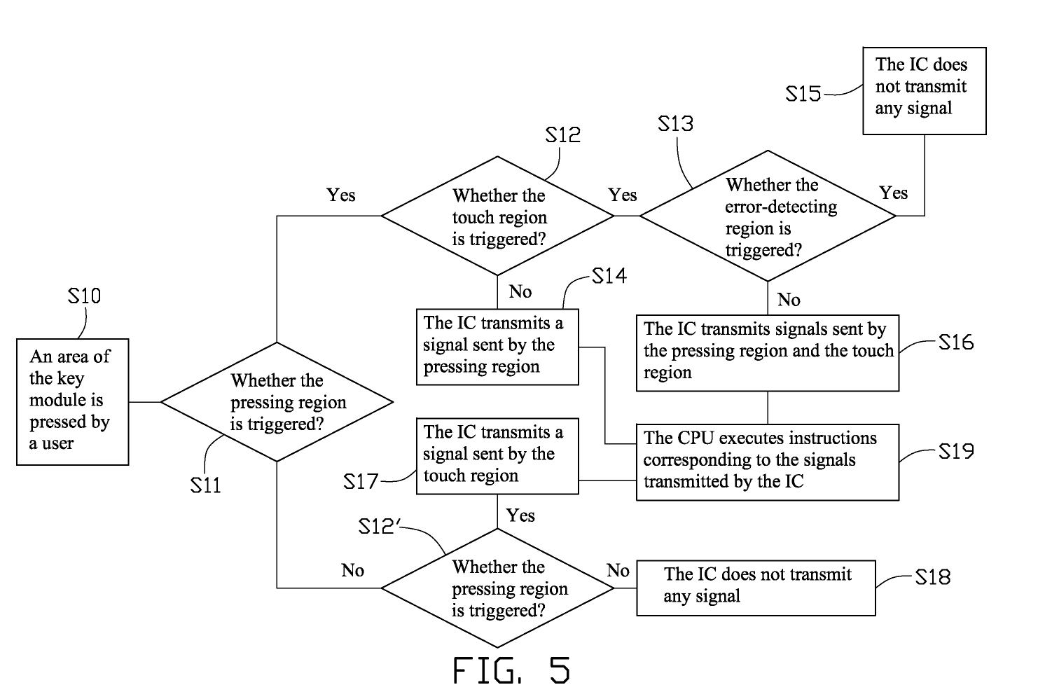

Referring also to FIG. 5, an anti-misoperation method for the key module 30 described above is provided.

In step S10, an area of the key module 30 is pressed by the user.

In step S11, if the pressing region 42 is triggered, the method continues to S12. If the pressing region 42 is not triggered, the method continues to step S12′.

In step S12, if the touch region 44 is triggered, the method continues to step S13. If the touch region 44 is not triggered, the method continues to step S14. In step S14, the IC 48 transmits a signal sent by the pressing region 42, and the method continues to step S19.

In step S13, if the error-detecting region 46 is triggered, the method continues to step S15. In step S15, the IC 48 does not transmit any signal. If the error-detecting region 46 is not triggered, the method continues to step S16. In step S16, the IC 48 transmits signals sent by the pressing region 42 and the touch region 44, and the method continues to step S19.

In step S12′, if the touch region 44 is triggered, the method continues to S17. In step S17, the IC 48 transmits a signal sent by the touch region 44, and the method continues to step S19. If the touch region 44 is not triggered, the method continues to step S18. In step S18, the IC 48 does not transmit any signal.

In step S19, the CPU 49 executes instructions corresponding to the signals transmitted by the IC 48.

It is believed that the present embodiments and their advantages will be understood from the foregoing description, and it will be apparent that various changes may be made thereto without departing from the spirit and scope of the disclosure or sacrificing all of its material advantages.

What is claimed is:

1. An electronic device, comprising:
a key module comprising a plurality of pressing keys and a plurality of touch keys;
at least one error-detecting touch key positioned between the pressing keys and the touch keys;
an active area positioned under the key module, and comprising a plurality of pressing regions under the pressing keys, a plurality of touch regions under the touch keys, and at least one error-detecting region under the at least one error-detecting touch key;
an integrated circuit (IC) electronically connected to the active area, the IC processing the signals sent by the pressing regions, the touch regions, or the at least one error-detecting region; and
a central processing unit (CPU) electronically connected to the IC to execute instructions corresponding to the signals processed by the IC.

2. The electronic device of claim 1, wherein areas between the pressing key and the touch key and between one touch key and another touch key have the at least one error-detecting touch key.

3. The electronic device of claim 1, wherein the touch keys are selected from the group consisting of capacitive keys, resistive keys, infrared keys, and surface acoustic-wave keys.

4. The electronic device of claim 1, wherein the at least one error-detecting touch key is selected from the group consisting of capacitive keys, resistance keys, infrared keys, and surface acoustic-wave keys.

5. The electronic device of claim 1, wherein the at least one error-detecting touch key is ring-shaped, and positioned around the pressing keys.

6. The electronic device of claim 1, wherein when one of the pressing keys is pressed by a user, one of the pressing regions is triggered to send a corresponding signal; when one of the touch keys or the error-detecting touch keys is touched by the user, one of the touch regions or the at least one error-detecting region is triggered to send another corresponding signal.

7. The electronic device of claim 6, wherein when one of the pressing region and the at least one error-detecting region are triggered simultaneously, the IC transmits the signal sent by the one of the pressing regions to the CPU.

8. The electronic device of claim 6, wherein when one of the touch regions and the at least one error-detecting region are triggered simultaneously, the IC transmits the signal sent by the one of the touch regions to the CPU.

9. The electronic device of claim 6, wherein when one of the pressing regions, one of the touch regions, and the at least one error-detecting region are triggered simultaneously, the IC does not transmit any signal to the CPU.

10. The electronic device of claim 6, wherein when one of the pressing regions and one of the touch regions are triggered simultaneously, but the at least one error-detecting region is not triggered, the IC transmit signals sent by the pressing region and the touch region to the CPU to further process.

11. The electronic device of claim 10, wherein an anti-misoperation control program is set in the electronic device to prevent the CPU from executing an error-instruction.

12. An anti-misoperation method for a key module comprising pressing keys and touch keys, the method comprising:
setting at least one error-detecting touch key between the pressing keys and touch keys, a plurality of pressing regions positioned under the pressing keys, a plurality of touch regions positioned under the touch keys, and at least one error-detecting region positioned under the at least one error-detecting touch key;
pressing an area of the key module, and determining which regions have been triggered;
upon a condition that one of the pressing region is triggered, but the touch regions are not triggered, the signal sent by the one of the pressing region is sent out;
upon a condition that the pressing regions are not triggered, but one of the touch regions is triggered, the signal sent by the one of the touch regions is sent out;
upon a condition that one of the pressing regions and one of the touch regions is triggered, but the at least one error-detecting region is not triggered, the signals sent by the one of the pressing regions and the one of the touch regions are sent out;
upon a condition that one of the pressing regions, one of the touch regions, and the at least one error-detecting region are all triggered, or that one of the pressing regions and one of the touch regions are both not triggered, no signal is sent out.

13. The anti-misoperation method of claim 12, wherein areas between the pressing regions and the touch regions and between one of the touch regions and another of the touch regions have the at least one error-detecting region.

14. The anti-misoperation method of claim 12, further comprising setting an IC electronically connected to the pressing regions, the touch regions, and the at least one error-detecting region, and a CPU electronically connected to the IC; the signals sent by the pressing regions, the touch regions, and the at least one error-detecting region are processed by the IC, and then are transmitted to the CPU to execute corresponding instructions.

15. The anti-misoperation method of claim 12, wherein the touch keys and the at least one error-detecting touch key are selected from the group consisting of capacitive keys, resistive keys, infrared keys, and surface acoustic-wave keys.
